(19) United States
(12) Patent Application Publication
(10) Pub. No.: US 2017/0200885 A1
(43) Pub. Date: Jul. 13, 2017

(54) Magnetic Memory Device

(71) Applicant: KOREA ADVANCED INSTITUTE OF SCIENCE AND TECHNOLOGY, Daejeon (KR)

(72) Inventors: Byong Guk Park, Daejeon (KR); Hae Yeon Lee, Seoul (KR)

(73) Assignee: KOREA ADVANCED INSTITUTE OF SCIENCE AND TECHNOLOGY, Daejeon (KR)

(21) Appl. No.: 15/346,170

(22) Filed: Nov. 8, 2016

(30) Foreign Application Priority Data
Jan. 11, 2016 (KR) 10-2016-0003151

(51) Int. Cl. H01L 43/08; H01L 43/10

(52) U.S. Cl. CPC H01L 43/08; H01L 43/10

(57) ABSTRACT

The present invention relates to a magnetic memory device comprising: a fixed magnetic layer; an insulation layer arranged on the fixed magnetic layer; a free magnetic layer arranged on the insulation layer; a second non-magnetic layer arranged on the free magnetic layer; and a first non-magnetic layer arranged on the second non-magnetic layer, wherein the second non-magnetic layer may include an element in the Periodic Table III-V periods.

### FIELD OF THE INVENTION

The present application relates to a magnetic memory device.

### BACKGROUND OF THE INVENTION

A magnetic memory device has desirable characteristics as a memory device, with a high speed, a low operation voltage, and a non-volatile characteristic. As disclosed in U.S. Pat. No. 5,699,293, a unit memory cell of the magnetic memory device is made up of a magnetoresistive sensor and a transistor.

One of the magnetic memory device structures may be a magnetic tunnel junction structure (a first magnetic electrode/an insulator/a second magnetic electrode) with two ferromagnetic materials separated by an insulation layer. The data is stored by the magnetoresistance having relative magnetization directions of the two magnetic materials. The magnetization directions of the two magnetic layers may be manipulated by a spin-polarized current, which is known as a spin transfer torque (STT) that is generated by angular momentum of electron.

A spin polarized current should pass through the magnetic tunnel junction structure in order to manipulate the magnetization direction by the spin-transfer torque. Meanwhile, a spin-orbit torque technology was recently developed for reversal of magnetization of a magnetic material by applying a horizontal current by placing metallic material in adjacent to the magnetic material to generate the spin current. See, U.S. Pat. No. 8,416,618, WRITABLE MAGNETIC MEMORY ELEMENT; US 2014-0169088, SPIN HALL MAGNETIC APPARATUS, METHOD AND APPLICATION; KR1266791, MAGNETIC MEMORY ELEMENT USING IN-PLANE CURRENT AND ELECTRIC FIELD.

As such, the spin-orbit torque needs to be improved in order to improve the magnetic memory device performance. To achieve the purpose, the present invention discloses various experimental results regarding the magnetic layers.

One of the technologies is to stack a non-magnetic layer on a free magnetic layer. However, the improvement in efficiency is limited due to limited types of the materials used for the first non-magnetic material of heavy metal having a high spin Hall angle and the magnetic material having a perpendicular anisotropy, which can be used for the double structure of the first non-magnetic material/the magnetic material to induce a magnetization reversal of the free magnetic layer by the spin orbit torque by a horizontal current.

Also, according to conventional experiments, it is known that the performance of the spin orbit torque is drastically reduced when the magnetic layer includes a layer including Cu or the like (Fan et al, Nature Commun. 5, 3042 (2014)).

### SUMMARY OF THE INVENTION

An object of the present invention is to provide a magnetic memory device, with an improved spin orbit torque, capable of increasing the switching efficiency, applying to various materials and architectures, reducing a critical current to reverse the magnetization, easily controlling the thickness of the insulation layer, and increasing stability of the magnetic memory device.

According to an embodiment of the present invention, a magnetic memory device comprise: a fixed magnetic layer; an insulation layer arranged on the fixed magnetic layer; a free magnetic layer arranged on the insulation layer; a second non-magnetic layer arranged on the free magnetic layer; and a first non-magnetic layer arranged on the second non-magnetic layer, wherein the second non-magnetic layer may include an element in the Periodic Table III-V periods.

Additionally, the second non-magnetic layer may comprise at least one selected from a group consisting of titanium (Ti), zirconium (Zr), vanadium (V), magnesium (Mg), chromium (Cr), molybdenum (Mo), aluminum (Al) and alloy thereof

Additionally, the first non-magnetic layer may comprise an element in the Periodic Table VI period.

Additionally, the first non-magnetic layer may comprise at least one selected from a group consisting of hafnium (Hf), tantalum (Ta), tungsten (W), iridium (Ir), platinum (Pt), palladium (Pd) and alloy thereof.

Additionally, the second non-magnetic layer may have a thickness in the range of 0.8 to 1.5 nm.

Additionally, the free magnetic layer may comprise at least one selected from a group consisting of iron (Fe), cobalt (Co), nickel (Ni), boron (B), silicon (Si), platinum (Pt), palladium (Pd) and alloy thereof.

Additionally, the device may further comprise a first electrode electrically connected to the fixed magnetic layer, and a second electrode electrically connected to the first non-magnetic layer.

Additionally, the insulation layer may comprise at least one selected from a group consisting of aluminum oxide, magnesium oxide, tantalum oxide and zirconium oxide.

Additionally, the fixed magnetic layer may comprise at least one selected from a group consisting of iron (Fe), cobalt (Co), nickel (Ni), boron (B), silicon (Si), zirconium (Zr), platinum (Pt), palladium (Pd) and alloy thereof.

Additionally, the fixed magnetic layer may include an antiferromagnetic layer or an artificial antiferromagnetic layer.

Additionally, the free magnetic layer may have a perpendicular anisotropy by aligning the magnetization direction in a perpendicular direction to the stacked direction.

Additionally, the magnetization direction of the free magnetic layer is characterized in changing by applying a horizontal current.

Additionally, the magnetic memory device may involve a magnetic tunnel junction structure.

The magnetic memory device according to an embodiment of the present invention enables an improved spin orbit torque, capable of increasing the switching efficiency.

Also, the magnetic memory device according to an embodiment of the present invention allows applying to various materials and architectures.

Also, the magnetic memory device according to an embodiment of the present invention allows reducing the critical current to reverse the magnetization, and reducing the power consumption.

Also, the magnetic memory device according to an embodiment of the present invention allows easily controlling the thickness of the insulation layer, and increasing stability of the magnetic memory device.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 shows a magnetic memory device according to an embodiment of the present invention.

FIG. 2 shows a stacked structure of a free magnetic layer, a second non-magnetic layer, a first non-magnetic layer and an insulation layer.

FIG. 3 is a top view of the stacked structure of the free magnetic layer, the second non-magnetic layer, the first non-magnetic layer and the insulation layer within a Hall bar pattern.

FIG. 4 shows a correlation between a z-axis magnetic field (H_{z}) and an anomalous Hall resistance (R_{H}) of the structure according to FIGS. 2 and 3.

FIG. 5 shows the anomalous Hall resistance representing a magnetization direction (M_{Z}) aligned in z-axis by applying a current at the structure according to FIGS. 2 and 3.

FIG. 6 shows magnetic hysteresis curves measured by using a vibrating sample magnetometer (VSM).

FIG. 7 shows a normalized anomalous Hall resistance (R_{H}) value according to a z-axis magnetic field (H_{z}) by the thickness of the second non-magnetic layer.

FIG. 8 shows a critical current (I_{C}) fluctuation depending on an insertion of the second non-magnetic layer.

FIG. 9 shows a switching efficiency according to a thickness of the second non-magnetic layer.

FIGS. 10 to 12 show the result regarding a magnetic field dependency of the spin orbit torque at a horizontal current density of the free magnetic layer.

FIGS. 13 and 14 show the effective magnetic field depending on an angle between the magnetization direction and the z-axis.

### DETAILED DESCRIPTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. The elements in the figures may show exaggeration in shapes and sizes, etc. for more detailed description. Like reference numerals designate like elements throughout the specification.

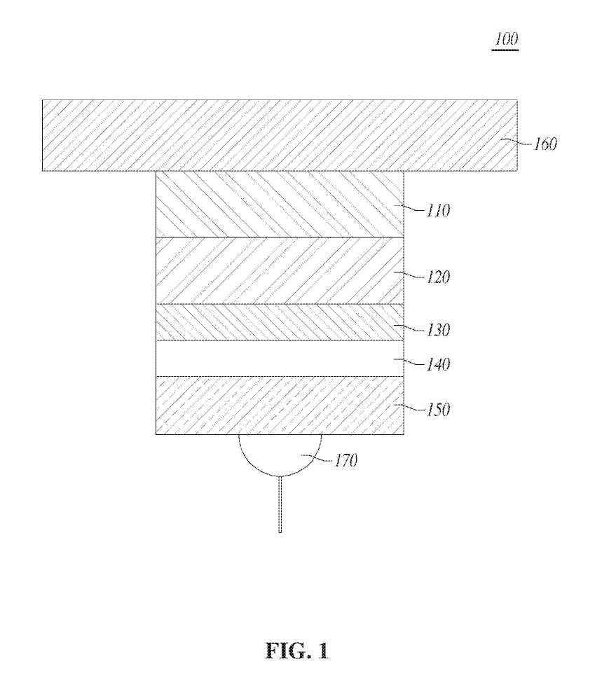

FIG. 1 shows a magnetic memory device 100 according to an embodiment of the present invention. Referring to FIG. 1, a magnetic memory device 100 according to an embodiment of the present invention comprises: a fixed magnetic layer 110; an insulation layer 120 arranged on the fixed magnetic layer 110; a free magnetic layer 130 arranged on the insulation layer 120; a second non-magnetic layer 140 arranged on the free magnetic layer 130; and a first non-magnetic layer 150 arranged on the second non-magnetic layer 140.

The magnetic memory device 100 may involve the magnetic tunnel junction structure having the fixed magnetic layer 110 and the free magnetic layer 130 separated by the insulation layer 120.

The fixed magnetic layer 110 among the two magnetic layers may have a perpendicular anisotropy to the stacked plane with a fixed magnetization direction.

To this end, the fixed magnetic layer 110 may comprise at least one selected from a group consisting of iron (Fe), cobalt (Co), nickel (Ni), boron (B), silicon (Si), zirconium (Zr), platinum (Pt), palladium (Pd) and alloy thereof.

Additionally, the fixed magnetic layer 110 may include an antiferromagnetic layer or an artificial antiferromagnetic layer. More specifically, the fixed magnetic layer 110 may comprise the antiferromagnetic layer or the artificial antiferromagnetic layer of a triple layer structure of the magnetic layer/the insulation layer/the magnetic layer. The antiferromagnetic layer is made of materials such as iridium (Ir), platinum (Pt), iron (Fe), manganese (Mn) and alloy thereof, or NiOx, CoOx, FeOx, etc. The artificial antiferromagnetic layer comprises the magnetic layer consisted of iron (Fe), cobalt (Co), nickel (Ni), boron (B), silicon (Si), zirconium (Zr), platinum (Pt), palladium (Pd) and alloy thereof, and the conductive layer consisted of ruthenium (Ru), copper (Cu), platinum (Pt), tantalum (Ta), titanium (Ti), tungsten (W), etc.

The insulation layer 120 is arranged between the fixed magnetic layer 110 and the free magnetic layer 130. The insulation layer 120 may block or restrict the electrical connection between the fixed magnetic layer 110 and the free magnetic layer 130. The insulation layer 120 may be formed by a conventional thin film forming process, with the thickness in the range of 1.6 to 3 nm.

The insulation layer 120 may comprise at least one selected from a group consisting of aluminum oxide, magnesium oxide, tantalum oxide and zirconium oxide, but not limited thereto.

The free magnetic layer 130 may have a changing magnetization direction, with a perpendicular anisotropy, as being arranged in an opposite direction of the fixed magnetic layer 110 on one side of the insulation layer 120.

To achieve this, the free magnetic layer may comprise at least one selected from a group consisting of iron (Fe), cobalt (Co), nickel (Ni), boron (B), silicon (Si), platinum (Pt), palladium (Pd) and alloy thereof.

Then, the free magnetic layer 130 may have a perpendicular anisotropy by aligning the magnetization direction in a perpendicular direction to the stacked direction. Additionally, the magnetization direction of the free magnetic layer 130 is characterized in changing by applying a horizontal current.

The second non-magnetic layer 140 is arranged on the free magnetic layer 130. The magnetic memory device 100 according to an embodiment of the present invention may retain the perpendicular anisotropy by comprising the second non-magnetic layer 140, and increases the spin current generated as an in-plane current by controlling the physical property of the interface and the spin orbit interaction.

It is already known that the spin current is reduced by inserting an interface layer such as Cu or the like (see Fan et al, Nature Commun. 5, 3042 (2014)). However, the magnetic memory device 100 according to an embodiment of the present invention may retain the perpendicular anisotropy of the free magnetic layer 130 by comprising the second non-magnetic layer 140 as the interface, and increases the spin current generated as the in-plane current and the switching efficiency by controlling for example the physical property of the interface and the spin orbit interaction.

To achieve this, the second non-magnetic layer 140 may include an element in the Periodic Table III-V periods. More specifically, the second non-magnetic layer 140 may comprise at least one selected from a group consisting of titanium (Ti), zirconium (Zr), vanadium (V), magnesium (Mg), chromium (Cr), molybdenum (Mo), aluminum (Al) and alloy thereof. Also, the second non-magnetic layer 140 may be light metal material.

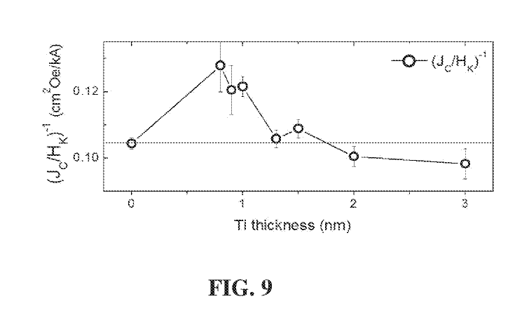

Additionally, as described in below referring to FIG. 9, the second non-magnetic layer 140 may have a thickness in the range of 0.8 to 1.5 nm, to further increase the switching efficiency of the magnetic memory device 100.

The first non-magnetic layer 150 is attached to the second non-magnetic layer 140, for the free magnetic layer 130 to retain the perpendicular anisotropy. To retain the perpendicular anisotropy of the free magnetic layer 130, the type of the second non-magnetic layer 140 is determined according to the type of the first non-magnetic layer 150.

The first non-magnetic layer 150 may include an element in the Periodic Table VI period. More specifically, the first non-magnetic layer 150 may comprise at least one selected from a group consisting of hafnium (Hf), tantalum (Ta), tungsten (W), iridium (Ir), platinum (Pt), palladium (Pd) and alloy thereof. Also, the first non-magnetic layer 150 may be heavy metal material.

The magnetic memory device according to an embodiment of the present invention comprises a triple structure of the free magnetic layer 130-the second non-magnetic layer 140-the first non-magnetic layer 150, where the spin-orbit torque is generated by applying the horizontal current to the triple structure, to reverse the magnetization direction depending on the current direction, allowing to manipulate the magnetization direction of the magnetic memory device 100 used as a memory element.

More specifically, the magnetic memory device 100 according to an embodiment of the present invention is provided to reverse the free magnetic layer 130 through the spin-orbit torque, using the horizontal current flowing on the non-magnetic material adjacent to the free magnetic layer 130 in the magnetic tunnel junction structure. It is distinguished from the conventional spin-transfer torque technology which is operated by the current of a vertical direction. Additionally, the magnetic memory device 100 according to an embodiment of the present invention has advantages in solving the drawbacks of the conventional high density magnetic memory, by a lower critical current density, a high thermal stability, and the reliability in the element.

The magnetic memory device 100 according to an embodiment of the present invention may further comprise a first electrode 160 electrically connected to the fixed magnetic layer 110, and a second electrode 170 electrically connected to the first non-magnetic layer 150.

The first electrode 160 and the second electrode 170 may inject the current respectively to the fixed magnetic layer 110 and the first non-magnetic layer 150. Therefore, the first electrode 160 and the second electrode 170 may comprise a conductive material. The first electrode 160 and the second electrode 170 may comprise at least one selected from the group consisting of nickel (Ni), tungsten (W), copper (Cu) and alloy thereof, but not limited thereto.

The magnetic memory device according to an embodiment of the present invention can be formed with the free magnetic layer 130, the insulation layer 120, the fixed magnetic layer 110, the first electrode 160 and the second electrode 170, using the conventional process of a film deposition, for example an atomic layer deposition (ALD), a chemical vapor deposition (CVD), a physical vapor deposition (PVD). The thicknesses of each layer may be in the range of nm to tens of nm, but not limited thereto.

The following is the examples and the experimental examples of the magnetic memory device according to the embodiments of the present invention.

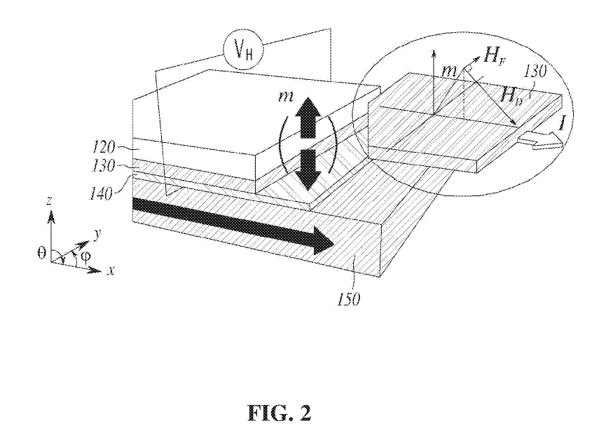

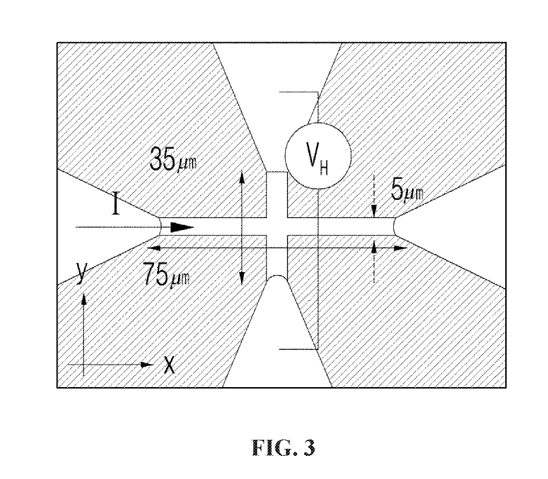

FIG. 2 shows a stacked structure of the free magnetic layer, the second non-magnetic layer, the first non-magnetic layer and the insulation layer. FIG. 3 shows a top view of the stacked structure of the free magnetic layer, the second non-magnetic layer, the first non-magnetic layer and the insulation layer within a Hall bar pattern. The experiment according to an embodiment of the present invention was conducted by using the structure of FIG. 3.

According to an embodiment of the present invention, FIG. 2 shows the free magnetic layer 130 includes CoFeB, the second non-magnetic layer 140 includes Pt, and the insulation layer 120 includes MgO. According to the experimental examples below, the second non-magnetic layer is formed in a thickness of 0 to 3 nm, and the free magnetic layer is formed in a thickness of 0.9 to 1 nm. The first non-magnetic layer is formed to be about 5 nm, and the insulation layer is formed to be about 1.6 nm. The above structure of the magnetic memory device is formed within Hall bar having a width of 5000 nm (see FIG. 3).

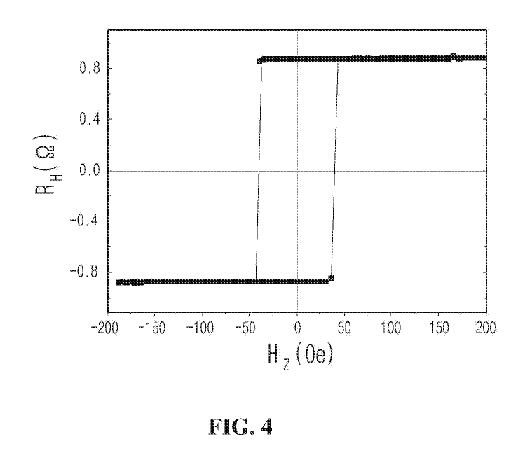

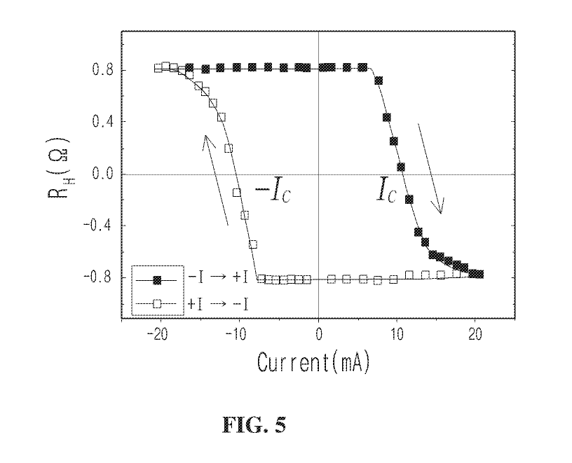

FIG. 4 shows a correlation between a z-axis magnetic field (H_{z}) and an anomalous Hall resistance (R_{H}) of the structure according to FIGS. 2 and 3. FIG. 5 shows a sweeping direction of current and the critical current (I_{C}) at the structure according to FIGS. 2 and 3. FIG. 4 depicts an anomalous Hall effect according to changes in a magnetic field.

Referring to FIGS. 4 and 5, the saturation anomalous Hall resistance measured by applying z-axis magnetic field in FIG. 4 is identical to the saturation anomalous Hall resistance (R_{H}) value measured by applying the current in FIG. 5, thereby the magnetization direction of the free magnetic field may be controlled by applying the current on the stacked plane, allowing a perfect switching.

Additionally, + current tends to make the magnetization direction to downward, and − current tends to make the magnetization direction to upward, in the magnetic field parallel to the current direction. It corresponds to a positive spin Hall angle of the first non-magnetic layer including platinum (Pt). Additionally, in FIG. 5, the width in an x-axis direction indicates the switching efficiency of the critical current (I_{C}) in the current inducing curve. According to the embodiment of the present invention, it is indicated that I_{C} of 11 mA (±3 mA) is needed to reverse the magnetization direction

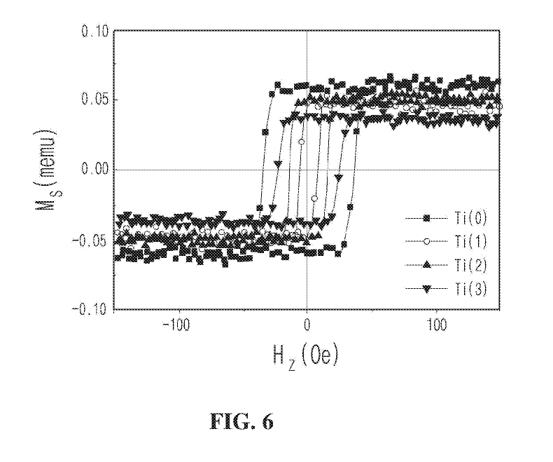

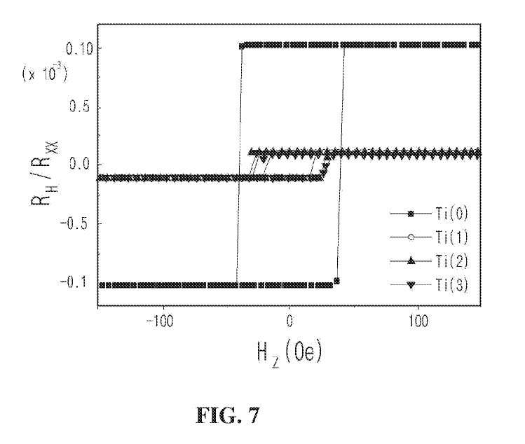

FIG. 6 shows magnetic hysteresis curves measured by using a vibrating sample magnetometer (VSM), by the thickness of the second non-magnetic layer. FIG. 7 shows a normalized anomalous Hall resistance (R_{H}) value according to the z-axis magnetic field (H_{z}) by the thickness of the second non-magnetic layer. FIG. 6 depicts the measured value of the magnetic hysteresis curve according to the changes in to the z-axis magnetic field (H_{z}). FIG. 7 represents the anomalous Hall resistance (R_{H}) normalized according to the resistance (Rxx) in a current direction according to the length.

FIGS. 6 and 7 show the changes in the magnetic and electrical characteristics depending on whether the second non-magnetic layer is included and the thickness thereof. Additionally, it shows that the perpendicular anisotropy property even by inserting the second non-magnetic layer.

Referring to FIG. 6, it is shown that the saturation magnetization (Ms) is gradually reduced as the thickness of the second non-magnetic layer increases. Also, as shown in FIG. 7, it is shown that anomalous Hall resistance (R_{H}) is highly dependent on whether the second non-magnetic layer is included or not.

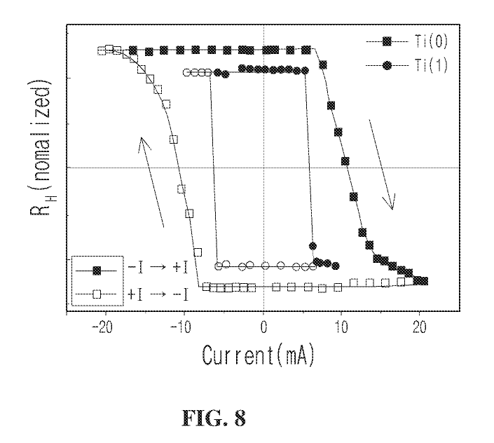

FIG. 8 shows a critical current (I_{C}) fluctuation depending on an insertion of the second non-magnetic layer. In FIG. 8, the thickness of the second non-magnetic layer is set to 1 nm.

When the horizontal current is increased on the free magnetic layer including the non-magnetic layer, the torque value is increased accordingly to reverse the magnetization direction of the free magnetic layer consequently. The current density to reverse the magnetization is the critical current density. The device with a smaller critical current density value is the device with a higher switching efficiency. To develop a highly integrated magnetic memory, the critical current density needs to be lowered, to ensure stability in the device and the power consumption. The switching efficiency may be influenced by the critical current (I_{C}), which may be represented by 1/I_{C}.

In FIG. 8, when the triple structure is formed with free magnetic layer/second non-magnetic layer/first non-magnetic layer (CoFeB/Ti/Pt) according to an embodiment of the present invention, the critical current is reduced by about 50%, compared to the case without the second non-magnetic layer. Therefore, it is shown that the magnetic memory device according to the embodiment of the present invention has an improved switching efficiency by increasing the spin orbit torque value, by including the second non-magnetic layer.

Table 1 and FIG. 9 show shows a switching efficiency according to a thickness of the second non-magnetic layer. Referring to Table 1 and FIG. 9, it is shown that the spin orbit torque efficiency ((Jc/Hk)⁻¹, Jc: critical current density, Hk: anisotropic magnetic field) is improved when the thickness of the second non-magnetic layer is in a range of 0.8 to 1.5 nm. Additionally, the spin orbit torque efficiency is further improved to be 0.12 (Jc/Hk)⁻¹ or greater when the thickness of the second non-magnetic layer is in a range of 0.8 to 1 nm.

TABLE 1

| thickness | spin orbit torque | |
|---|---|---|
| (nm) of second non- | efficiency | error of spin orbit |
| magnetic layer (Ti) | ((Jc/Hk)−1) | torque efficiency |
| 0 | 0.10436 | 0.0017 |
| 0.8 | 0.12788 | 0.008 |
| 0.9 | 0.1205 | 0.0075 |
| 1 | 0.12151 | 0.003 |
| 1.3 | 0.10583 | 0.0027 |
| 1.5 | 0.10889 | 0.00277 |
| 2 | 0.1005 | 0.003 |
| 3 | 0.09833 | 0.0045 |

The improved spin orbit torque represents the reduced critical current (I_{C}) and the increased switching efficiency. Thus, according to an embodiment of the present invention, the magnetic memory device is further improved in the switching efficiency by forming the thickness of the second non-magnetic layer in a range of 0.8 to 1.5 nm.

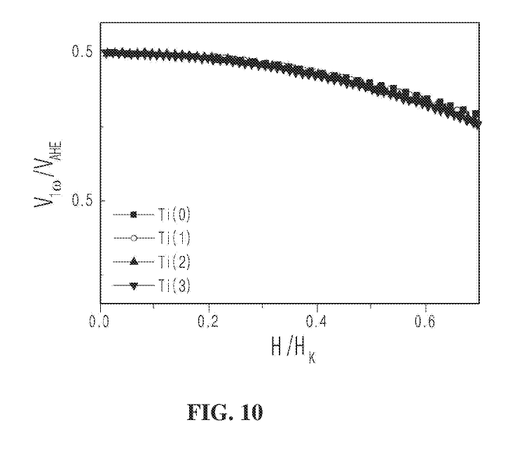

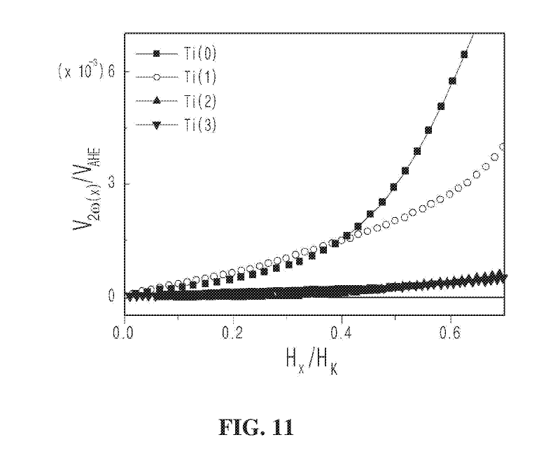

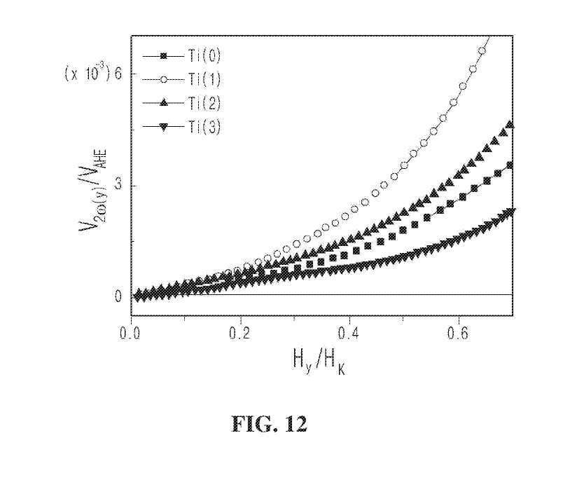

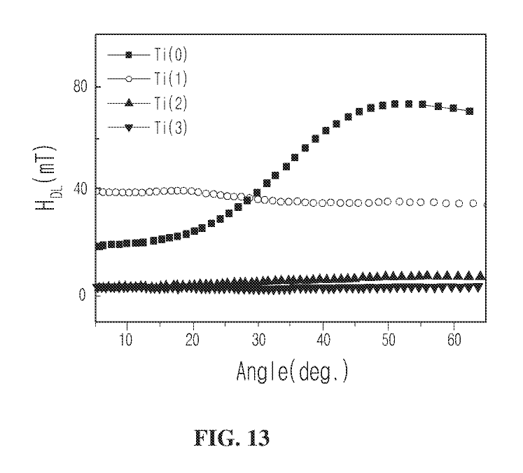

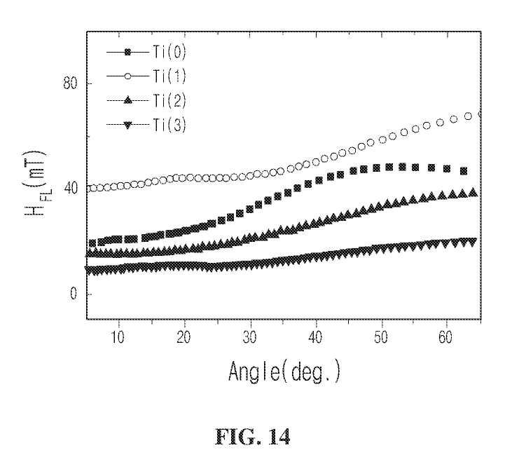

FIGS. 10 to 12 show the result of changes in the spin orbit torque of the free magnetic layer by applying a horizontal current, and also show the result regarding a magnetic field dependency of the spin orbit torque at a horizontal current density of the free magnetic layer. FIGS. 13 and 14 show the effective magnetic field depending on a polar angle between a magnetization direction and the z-axis, based on the result according to FIGS. 10 to 12. The spin orbit torque may be compared by FIG. 13.

In FIGS. 13 and 14, it is shown that the spin orbit torque value in a range of the angle between magnetization direction and the z-axis is 20 degree or less is higher by 2 to 2.5 times when the second non-magnetic layer having a thickness of 1 nm is inserted, compared to the case without the second non-magnetic layer. As such, it represents that the switching efficiency is increased when the spin orbit torque value is increased.

While the present application has been particularly shown and described with respect to various embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

The invention claimed is:

1. A magnetic memory device comprising:
a fixed magnetic layer;
an insulation layer arranged on the fixed magnetic layer;
a free magnetic layer arranged on the insulation layer;
a second non-magnetic layer arranged on the free magnetic layer; and
a first non-magnetic layer arranged on the second non-magnetic layer, wherein the second non-magnetic layer may include an element in the Periodic Table III-V periods.

2. A magnetic memory device according to claim 1, wherein the second non-magnetic layer comprises at least one selected from a group consisting of titanium (Ti), zirconium (Zr), vanadium (V), magnesium (Mg), chromium (Cr), molybdenum (Mo), aluminum (Al) and alloy thereof.

3. A magnetic memory device according to claim 1, wherein the first non-magnetic layer comprises an element in the Periodic Table VI period.

4. A magnetic memory device according to claim 1, wherein the first non-magnetic layer comprises at least one selected from a group consisting of hafnium (Hf), tantalum (Ta), tungsten (W), iridium (Ir), platinum (Pt), palladium (Pd) and alloy thereof.

5. A magnetic memory device according to claim 1, wherein the second non-magnetic layer has a thickness in a range of 0.8 to 1.5 nm.

6. A magnetic memory device according to claim 1, wherein the free magnetic layer comprises at least one selected from a group consisting of iron (Fe), cobalt (Co), nickel (Ni), boron (B), silicon (Si), platinum (Pt), palladium (Pd) and alloy thereof.

7. A magnetic memory device according to claim 1, wherein the device further comprises a first electrode electrically connected to the fixed magnetic layer, and a second electrode electrically connected to the first non-magnetic layer.

8. A magnetic memory device according to claim 1, wherein the second non-magnetic layer enables the free magnetic layer to retain a perpendicular anisotropy.

9. A magnetic memory device according to claim 1, wherein the second non-magnetic layer comprises at least one selected from a group consisting of iron (Fe), cobalt (Co), nickel (Ni), boron (B), silicon (Si), silicon (Si), zirconium (Zr), platinum (Pt), palladium (Pd) and alloy thereof.

10. A magnetic memory device according to claim 1, wherein the fixed magnetic layer comprises an antiferromagnetic layer or an artificial antiferromagnetic layer.

11. A magnetic memory device according to claim 1, wherein the free magnetic layer has a perpendicular anisotropy by aligning the magnetization direction in a perpendicular direction to the stacked direction.

12. A magnetic memory device according to claim 1, wherein the magnetization direction of the free magnetic layer is characterized in changing by applying a horizontal current.

13. A magnetic memory device according to claim 1, wherein the magnetic memory device involves a magnetic tunnel junction structure.
